(19) United States
(12) Patent Application Publication
(10) Pub. No.: US 2010/0181661 A1
(43) Pub. Date: Jul. 22, 2010

(54) SEMICONDUCTOR DEVICE

(75) Inventors: Yasuo TAKEMOTO, Yokohama-shi (JP); Hideo TAGUCHI, Fujisawa-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/685,977

(22) Filed: Jan. 12, 2010

(30) Foreign Application Priority Data
Jan. 19, 2009 (JP) 2009-008874

(51) Int. Cl. H01L 25/065; H01L 23/52

(52) U.S. Cl. 257/686; 257/690; 257/723; 257/E23.141; 257/E25.013

(57) ABSTRACT

A semiconductor device includes a chip unit mounted on a wiring board. The chip unit includes of semiconductor chips having electrode pads and an interposer having test pads exposed and electrode pads wired from the test pads. The semiconductor chips and the interposer are stacked in a step-like shape so as to be positioned the interposer in an uppermost level. The electrode pads of the semiconductor chips and the interposer are electrically connected by first connecting members, and the electrode pads of the semiconductor chips or the interposer and the wiring board are electrically connected by second connecting members.

### CROSS REFERENCE TO RELATED APPLICATIONS

This application is based upon and claims the benefit of priority from the prior Japanese Patent Application No. 2009-008874, filed on Jan. 19, 2009; the entire contents of which are incorporated herein by reference.

### BACKGROUND OF THE INVENTION

A memory card (semiconductor memory card) housing a NAND-type flash memory or the like is in a rapid trend of getting smaller and having a higher capacity. In order to realize a miniaturized memory card, semiconductor chips such as memory chips and controller chips or the like are mounted by being stacked on a wiring board. In order to realize a higher capacity in a memory card, the memory chips themselves are stacked in multiple layers, and the stacked number of the memory chips tends to increase.

An inspection of electric characteristics of the semiconductor chips such as the memory chips is generally performed, in addition to an inspection on a wafer, after a semiconductor package (semiconductor device) is assembled as well. In this case, since acceptance or non-acceptance of the electric characteristics is judged as the stacked semiconductor chips as a whole, even with an initial failure or a problem occurring in one of the stacked semiconductor chips, the semiconductor package as a whole is regarded as defective. In the inspection after assembly of the semiconductor package, a yield of the semiconductor package is obtained as a power of the stack number of a yield per chip, so that the yield of the semiconductor package is decreased as the semiconductor chips to be stacked increase.

Thus, it is desired to reduce a yield loss based on the initial failure or problem of the semiconductor chip in the inspection after assembly of the semiconductor package and to increase the yield of the semiconductor package itself. With regard to a mounting structure of the semiconductor chips, various suggestions have been presented conventionally. There is described in JP-A 2008-147226 (KOKAI) a structure in which a plurality of memory chips are stacked in a step-like shape and a controller chip and a relay wiring board are disposed on the memory chip of an uppermost level. The relay wiring board electrically connects the memory chips and the controller chip, and does not have other functions.

In JP-A 2003-203952 (KOKAI), there is described that a plurality of semiconductor chips and a substrate are temporarily joined by a magnetic force to form a multi-layered body and judgment of acceptance or non-acceptance of electric characteristics of the multi-layered body, thereafter a heat processing is performed on the multi-layered body which has been judged to be acceptable in terms of electric characteristics so that the semiconductor chips and the substrate are permanently joined, whereby a semiconductor module is fabricated. A solder bump is applied for connecting the semiconductor chip and the substrate. Therefore, the above technology cannot be applied to a semiconductor module having a general purpose connection structure such as wire-bonding. Besides, the magnetic power is used to form the multi-layered body, a specialized apparatus such as a ferromagnetic plate is required.

### BRIEF SUMMARY OF THE INVENTION

A semiconductor device according to a first aspect of the invention includes: a wiring board having internal connection terminals; a chip unit having a plurality of semiconductor chips and an interposer stacked on the wiring board in a step-like shape so that the interposer is positioned in an uppermost level, each of the semiconductor chips having electrode pads exposed, and the interposer having test pads exposed and electrode pads wired from the test pads and exposed; first connecting members electrically connecting between the electrode pads of the semiconductor chips and the interposer; second connecting members electrically connecting the internal connection terminals of the wiring board and the electrode pads of the semiconductor chip or the interposer; and a sealing resin layer formed on the wiring board to seal the chip unit together with the first and second connecting members.

A semiconductor device according to a second aspect of the present invention includes: a wiring board having internal connection terminals; a chip unit having a plurality of semiconductor chips stacked on the wiring board in a step-like shape, each of the semiconductor chips having electrode pads exposed; first connecting members electrically connecting between the electrode pads of the semiconductor chips; second connecting members electrically connecting the internal connection terminals of the wiring board and the electrode pads of the semiconductor chip; and a sealing resin layer formed on the wiring board to seal the chip unit together with the first and second connecting members, wherein the semiconductor chip positioned in at least an uppermost level of the chip unit has test pads rewired from the electrode pads and exposed.

### BRIEF DESCRIPTION OF THE DRAWINGS

FIG. 1 is a cross-sectional view showing a semiconductor device of a first embodiment.

FIG. 2 is a cross-sectional view showing a modified example of the semiconductor devices shown in FIG. 1.

FIG. 3 is a plan view showing a manufacturing process of the semiconductor device shown in FIG. 1.

FIG. 4 is a cross-sectional view along a line A-A in FIG. 3.

FIG. 5 is a cross-sectional view showing a semiconductor device of a second embodiment.

FIG. 6 is a cross-sectional view showing a modified example of the semiconductor device shown in FIG. 5.

FIG. 7 is a plan view showing a manufacturing process of the semiconductor device shown in FIG. 5.

FIG. 8 is a cross-sectional view along a line A-A in FIG. 7.

### DETAILED DESCRIPTION OF THE INVENTION

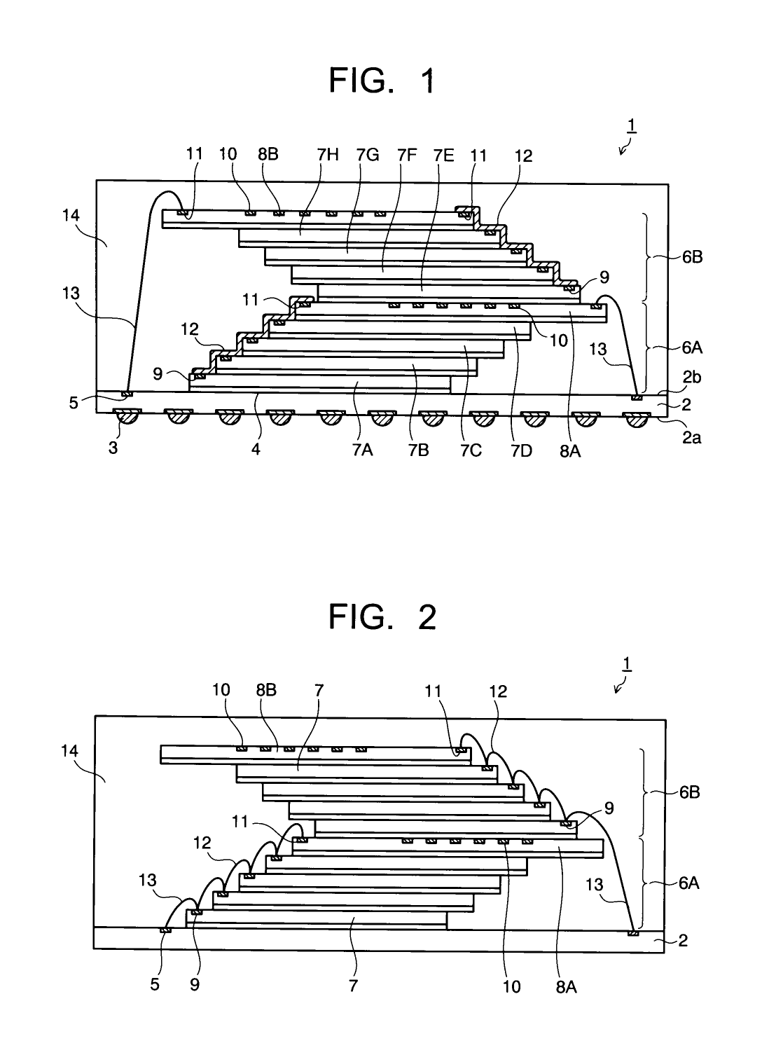

Hereinafter, embodiments for practicing the present invention will be described with reference to the drawings. FIG. 1 is a view showing a constitution of a semiconductor device according a first embodiment of the present invention. The semiconductor device 1 includes a wiring board 2. The wiring board 2 is an insulating resin board inside of which or on a surface of which a wiring network is provided, and more specifically a print wiring board to which a glass-epoxy resin, a BT resin (Bsmaleimide-Triazine resin) or the like is used is applied. The wiring board 2 has a first surface 2a being a terminal formation surface and a second surface 2b being a chip mounting surface.

External connection terminals 3 are formed on the first surface 2a of the wiring board 2. When a BGA package is constituted by the semiconductor device 1, the external connection terminals 3 are constituted by projecting terminals by solder balls or the like. When an LGA package is constituted by the semiconductor device 1, metal lands are provided as the external connection terminals. The semiconductor device 1 is not limited for the BGA package or the LGA package but the semiconductor device 1 can be also applied to a semiconductor memory card or the like. In such a case, input/output terminals of the semiconductor memory card are formed on the first surface 2a of the wiring board 2.

A chip mounting portion 4 and internal connection terminals 5 are provided on the second surface 2b of the wiring board 2. The internal connection terminals 5 are connection pads functioning as connecting portion at a connection time (at a time of wire bonding for example) of the wiring board 2 and the semiconductor chip. The internal connection terminals 5 are electrically connected to the external connection terminals 3 via a not-shown wiring network of the wiring board 2. A chip unit 6 is mounted on the chip mounting portion 4 of the wiring board 2. FIG. 1 shows a state that two sets of chip units 6A, 6B are stacked on the second surface 2b of the wiring board 2.

The first chip unit 6A has a plurality of semiconductor chips 7A to 7D stacked on the chip mounting portion 4 and an interposer 8A stacked thereon. The second chip unit 6B has a plurality of semiconductor chips 7E to 7H stacked on the first chip unit 6A and an interposer 8B stacked thereon. The interposers 8A and 8B are positioned in uppermost levels of the chip units 6A, 6B, respectively. The interposer 8 has an external shape of a rectangle similarly to the semiconductor chip 7.

The semiconductor chip 7 has electrode pads 9 arranged along one outer edge (one shorter edge for example). The interposer 8 has test pads 10 and electrode pads 11. The test pads 10 of the interposer 8 are wired from the electrode pads 11. The test pads 10 and the electrode pads 11 are electrically connected via an internal wiring or a surface wiring provided in the interposer 8. The electrode pads 11 of the interposer 8 are arranged along at least one outer edge. The electrode pads 11 of the interposer 8 shown in FIG. 1 are arranged along the same first outer edge (first shorter edge) as the edge along which the pad of the semiconductor chip 7 is arranged and along a second outer edge (second shorter edge) opposed to the first outer edge.

In the first chip unit 6A, the plural semiconductor chips 7A to 7D and the interposer 8A are stacked in the step-like shape to expose the electrode pads 9, 11 thereof. In the second chip unit 6B, similarly to the above, the plural semiconductor chips 7E to 7H and the interposer 8B are stacked in the step-like shape to expose the electrode pads 9, 11. In the second chip unit 6B, a stepped direction of the plural semiconductor chips 7E to 7H and the interposer 8B is in a reverse direction of a stepped direction of the first chip unit 6A.

The semiconductor device 1 shown in FIG. 1 includes the chip unit 6A constituted by the four semiconductor chips 7A to 7D and the interposer 8A and the chip unit 6B constituted by the four semiconductor chips 7E to 7H and the interposer 8B. The number of the semiconductor chips 7 constituting the chip units 6A, 6B is not limited to four but is appropriately set in correspondence with a type or a function of the semiconductor device 1. The chip units 6A, 6B are each constituted by four to eight semiconductor chips 7. The stacked number of the chip unit 6 is not limited to two either and can be one or plural.

The electrode pads 9, 11 of the semiconductor chips 7A to 7D and the interposer 8A constituting the first chip unit 6A are electrically connected by first connecting members 12. Similarly, the electrode pads 9, 11 of the semiconductor chips 7E to 7H and the interposer 8B constituting the second chip unit 6B are also electrically connected by first connecting members 12. A conductive layer made of a coating layer of a conductive paste or a metal wire formed by wire bonding is applied to the first connecting member 12. The conductive layer as the first connecting member is formed by application of the conductive paste in correspondence with a desired wiring pattern for example, by applying an ink jet method and a printing method using a mask such as a screen printing method.

In the chip units 6A, 6B shown in FIG. 1, the electrode pads 9, 11 of the semiconductor chips 7 and the interposers 8 are each connected by the first connecting members 12 made of the conductive layers. The conductive layer is formed along the step-like shape of the semiconductor chips 7 and the interposer 8. In the chip units 6A, 6B shown in FIG. 2, the electrode pads 9, 11 of the semiconductor chips 7 and the interposers 8 are each connected by the first connecting members 12 made of the metal wires. The electrode pads 9, 11 shown in FIG. 2 are sequentially connected by the metal wires. The electrode pads 9, 11 of the semiconductor chips 7 and the interposers 8 are electrically connected by the first connecting members 12 made of the conductive layers or the metal wires.

As a concrete example of the semiconductor chips 7A to 7H, semiconductor memory chips such as NAND type flash memories can be cited. A controller chip can be disposed as necessary on the stacked semiconductor memory chips. The semiconductor device 1 having the semiconductor memory chips as the semiconductor chips 7A to 7H constitutes a semiconductor memory device. The interposers 8A, 8B may be any interposers that have a function by test pads 10 and have electrode pads 11 connected thereto, and are constituted by semiconductor chips for relay (Si interposer) which do not have element structures. The interposers 8A, 8B can be constituted by wiring boards such as print wiring boards.

The first and second chip units 6A, 6B are electrically connected to the wiring board 2 via second connecting members 13 made of metal wires. FIG. 1 shows a state that the electrode pads 11 of the interposers 8A, 8B and the connection pads 5 of the wiring board 2 are electrically connected via the metal wires. In the first chip unit 6A, the electrode pads 11 of the interposer 8A are connected to the electrode pads 9 of the semiconductor chips 7A to 7D via the first connecting members 12. The semiconductor chips 7A to 7D are electrically connected to the wiring board 2 via the interposer 8A. The connection structure in the second chip unit 6B is similar to that in the first chip unit 6A.

The semiconductor device 1 shown in FIG. 1 has the conductive layer as the first connecting member 12. Since wire-bonding to the electrode pad 9 covered by the conductive layer is difficult, the electrode pad 11 of the interposer 8 and the connection pad 5 of the wiring board 2 are connected by the metal wire. The electrode pads 11 arranged along the first outer edge of the interposer 8 is electrically connected to the electrode pads 9 of the semiconductor chip 7 via the first connecting members 12 made of the conductive layers. The electrode pads 11 arranged along the second outer edge of the interposer 8 are electrically connected to the connection pads 5 of the wiring board 2 via the second connecting members 13 made of the metal wires.

The semiconductor device 1 shown in FIG. 2 has the metal wire as the first connecting member 12. In such a case, the electrode pads 9 of the semiconductor chip 7 and the connection pads 5 of the wiring board 2 can be connected by the metal wires. The electrode pads 11 of the interposer 8 are electrically connected to the electrode pads 9 of the semiconductor chip 7 via the first connecting members 12 made of the metal wires, and are further electrically connected to the connection pads 5 of the wiring board 2 via the second connecting members 13 made of the metal wires. In either case, the semiconductor chips 7 constituting the chip units 6A, 6B are electrically connected to the wiring board 2 via the second connecting members 13.

A sealing resin layer 14 made of an epoxy resin for example is formed by molding on the second surface 2b of the wiring board 2 on which the first and second chip units 6A, 6B are mounted. The semiconductor chips 7A to 7D and the interposer 8A constituting the first chip unit 6A and the semiconductor chips 7E to 7H and the interposer 8B constituting the second chip unit 6B together with the first and second connecting members 12, 13 are integrally resin-sealed by the sealing resin layer 14. The semiconductor device 1 used as a semiconductor memory device or the like is constituted thereby.

In the first and second chip units 6A, 6B, electric characteristics of the plural semiconductor chips 7A to 7D and 7E to 7H are inspected in advance by using the test pads 10 of the interposers 8A, 8B, so that judgment of acceptance or non-acceptance of the electric characteristics as the chip units 6A, 6B is done. Only the chip units 6 that have been judged to be acceptable in terms of electric characteristics in the inspection using the test pads 10 of the interposers 8A, 8B are mounted on the wiring board 2. As described above, as a result of fabricating the semiconductor device 1 by mounting the chip units 6A, 6B having been judged to be acceptable in terms of electronic characteristics on the wiring board 2, a yield loss of the semiconductor chip 7 can be reduced and a manufacturing yield of the semiconductor device 1 itself can be improved.

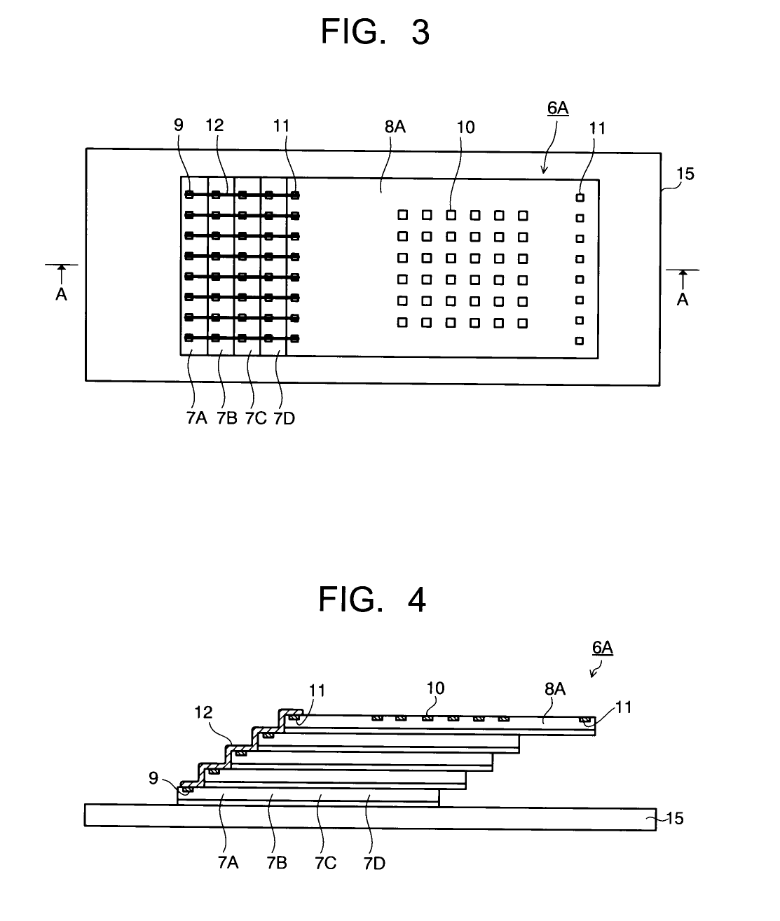

A concrete manufacturing process of first and second chip units 6A, 6B will be described with reference to FIG. 3 and FIG. 4. The first and second chip units 6A, 6B are fabricated by the same manufacturing process. FIG. 3 and FIG. 4 show the manufacturing process of the first chip unit 6A. First, a plurality of semiconductor chips 7A to 7D are stacked on a support plate 15 and further an interposer 8A is stacked in an uppermost level. The plural semiconductor chips 7A to 7D and the interposer 8A are stacked in a step-like shape to expose electrode pads 9, 11 thereof. The plural semiconductor chips 7A to 7D and the interposer 8A are bonded via bonding layers.

As the support plate 15, an adhesive tape or an adhesive sheet to/from which the chip unit 6A can be attached/detached is used. When an inspection of the chip unit 6A is performed in a state of being mounted on the support plate 15, a support plate 15 having a structure capable of being set in an inspection device such as a tester for a package is used. For example, there is used a support plate 15 constituted by applying an adhesive tape or an adhesive sheet on a lower surface side of a metal frame. The chip unit 6A is bonded on an upper surface side of the adhesive tape or the adhesive sheet. Detachment of the chip unit 6A is performed by removing adhesion by radiating an ultraviolet ray or the like from the lower surface side of the adhesive tape or the adhesive sheet for example.

Next, a conductive layer for example is formed on the semiconductor chips 7A to 7D and the interposer 8A stacked on the support plate 15, so that electrode pads 9, 11 of the semiconductor chips 7A to 7D and the interposer 8A are electrically connected by first connecting members 12 made of the conductive layers. The chip unit 6A having the semiconductor chips 7A to 7D and the interposer 8A is fabricated as described above. Since the electrode pads 11 of the interposer 8A are wired from test pads 10, the electrode pads 9 of the plural semiconductor chips 7A to 7D are in a state of being electrically connected to the test pads 10 via the first connecting members 12 and the interposer 8A.

Further, since the interposer 8A is stacked in the uppermost level of the chip unit 6A, the test pads 10 formed on its surface is exposed on a top surface of the chip unit 6A. Therefore, contacting the test pads 10 with test terminals of the inspection device enables judgment of acceptance or non-acceptance of the electric characteristics of the plural semiconductor chips 7A to 7D as the chip unit 6A. The inspection of the chip unit 6A can be performed on the support plate 15 or can be performed after the chip unit 6A is detached from the support plate 15.

Thereafter, the chip unit 6A having been judged to be acceptable in terms of electric characteristics in the inspection using the test pads 10 of the interposer 8A is detached from the support plate 15 and transported to a mounting process. Otherwise, an inspection is performed after detachment from the support plate 15 in advance, and the chip unit 6A judged to be acceptable in terms of electric characteristics is transferred to the mounting process. After mounting such a chip unit 6A on a wiring board 2, through a connecting process of the chip unit 6A and the wiring board 2 by second connecting members 13, a resin sealing process and so on, an intended semiconductor device 1 is fabricated. Procedures are similar also in a case that a plurality of chip units 6A, 6B are stacked on the wiring board 2, and only chip units 6A, 6B having been judged non-defective are used to fabricate the semiconductor device 1.

As described above, stacking of the interposer 8 having the test pads 10 in the uppermost level of the chip unit 6 enables the inspection of the semiconductor chip 7 in a stage of the chip unit 6. Besides, since the electrode pads 9, 11 of the semiconductor chips 7 and the interposer 8 are electrically connected in the stage of the chip unit 6, the inspection of the semiconductor chip 7 can be performed by using the test pads 10 of the interposer 8. Further, by fabricating the semiconductor device 1 by mounting only the chip unit 6 judged to be acceptable in terms of electric characteristics on the wiring board 2, a yield loss of the semiconductor chip 7 can be reduced and a manufacturing yield of the semiconductor device 1 itself can be improved.

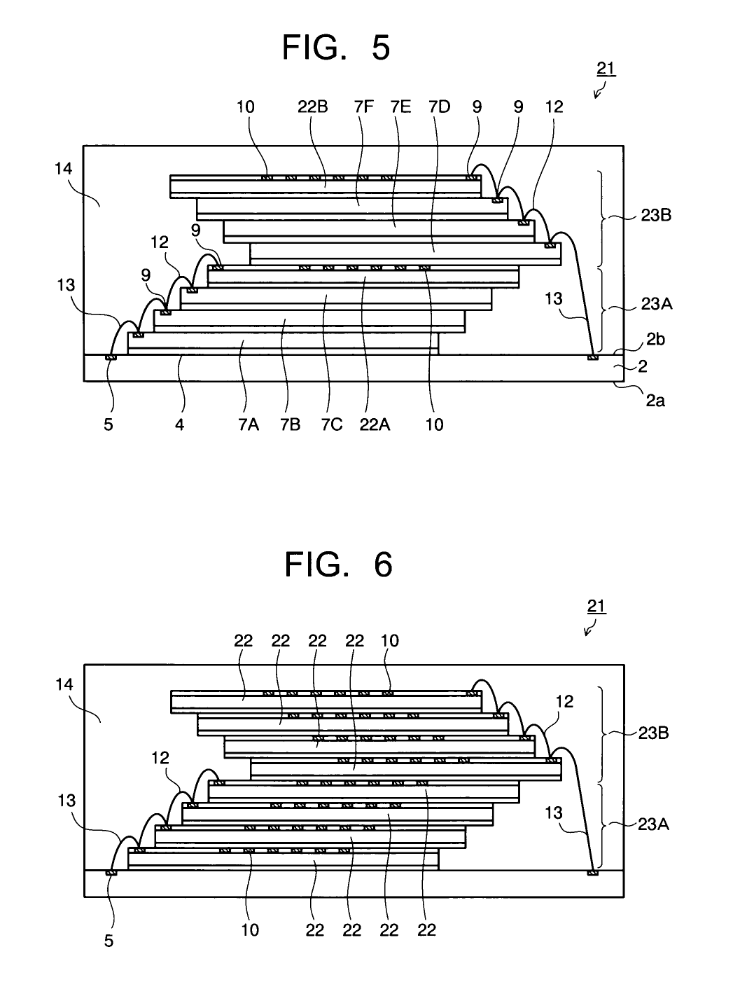

Next, a semiconductor device according to a second embodiment of the present invention will be described with reference to FIG. 5. A semiconductor device 21 shown in FIG. 5 has a constitution similar to that of the semiconductor 1 of the first embodiment except that semiconductor chips 22 (22A, 22B) having test pads 10 are stacked in uppermost levels of chip units 23A, 23B instead of the interposers 8 in the semiconductor device 1 of the first embodiment. In the semiconductor device 21 shown in FIG. 5, the first and second chip units 23, 23B are stacked on a wiring board 2.

The first chip unit 23A has a plurality of semiconductor chips 7A, 7B, 7C, 22A stacked on the wiring board 2 in a step-like shape. The second chip unit 23B has a plurality of semiconductor chips 7D, 7E, 7F, 22B stacked on the first chip unit 23A in a step-like shape. The semiconductor chips 22A, 22B positioned in the uppermost levels among the semiconductor chips constituting the chip units 23A, 23B have the test pads 10 which are rewired from electrode pads 9 and exposed on surfaces. The semiconductor chips 22A, 22B having the test pads 10 perform similar functions to those of the interposers 8 in the first embodiment.

The semiconductor chip 7 has the electrode pads 9 arranged along one outer edge (one shorter edge for example). The semiconductor chip 22 has the electrodes 9 and the test pads 10. The test pads 10 of the semiconductor chip 22 are wired from the electrode pads 9. The electrode pads 9 and the test pads 10 are electrically connected via a rewiring layer formed on the semiconductor chip 22. The electrode pads 9 of the semiconductor chip 22 are arranged along at least one outer edge. The electrode pads 9 of the semiconductor chip 22 shown in FIG. 5 are arranged along the same outer edge (one shorter edge for example) as the edge along which the pads of the semiconductor chip 7 is arranged.

The semiconductor device 21 of the second embodiment basically has a similar constitution to that of the first embodiment. For example, the semiconductor device 21 constitutes a BGA package, an LGA package, or a semiconductor memory card. The semiconductor chips 7, 22 constitute semiconductor memory chips such as NAND type flash memories. The semiconductor chips 22A, 22B having the test pads 10 are fabricated by, after fabrication in a similar process to that for an ordinary semiconductor chip, forming the test pads 10 on surfaces and simultaneously forming the rewiring layers from the test pads 10 to the electrode pads 9.

The electrode pads 9 of the semiconductor chips 7A, 7B, 7C, 22A constituting the first chip unit 23A are electrically connected by first connecting members 12. Similarly, the electrode pads 9 of the semiconductor chips 7D, 7E, 7F, 22B constituting the second chip unit 23B are also electrically connected by first connecting members 12. FIG. 5 shows the semiconductor device 21 to which metal wires are applied as the first connecting members 12. The first connecting member 12 can be constituted by a conductive layer similarly to in the semiconductor device 1 shown in FIG. 1.

The first and second chip units 23A, 23B are electrically connected to the wiring board 2 via second connecting members 13. In the semiconductor device 21 shown in FIG. 5, the electrode pads 9 of the semiconductor chips 7A, 7D positioned in lowermost levels of the respective chip units 23A, 23B are electrically connected to the connection pads 5 of the wiring board 2 via metal wires being the second connecting members 13. It should be noted that though a structure is shown in FIG. 5 in which only the semiconductor chips 22A, 22B positioned in the uppermost levels of the chip units 23A, 23B have the test pads 10, the structure of the semiconductor device 21 is not limited thereto. As shown in FIG. 6, all the semiconductor chips 22 constituting the chip units 23A, 23B can have the test pads 10.

The first and second chip units 23A, 23B are inspected in terms of electric characteristics by using the test pads 10 of the semiconductor chips 22A, 22B positioned in the uppermost levels in advance, whereby acceptance or non-acceptance of the electric characteristic as the chip units 23A, 23B is judged. Only the chip units 23A, 23B having been judged to be acceptable in terms of electric characteristics in the inspection using the test pads 10 of the semiconductor chips 22A, 22B are mounted on the wiring board 2. As described above, as a result of fabricating the semiconductor device 21 by mounting the chip units 23A, 23B having been judged to be acceptable in terms of electric characteristics on the wiring board 2, yield losses of the semiconductor chips 7, 22 can be reduced and a manufacturing yield of the semiconductor device 21 itself can be improved.

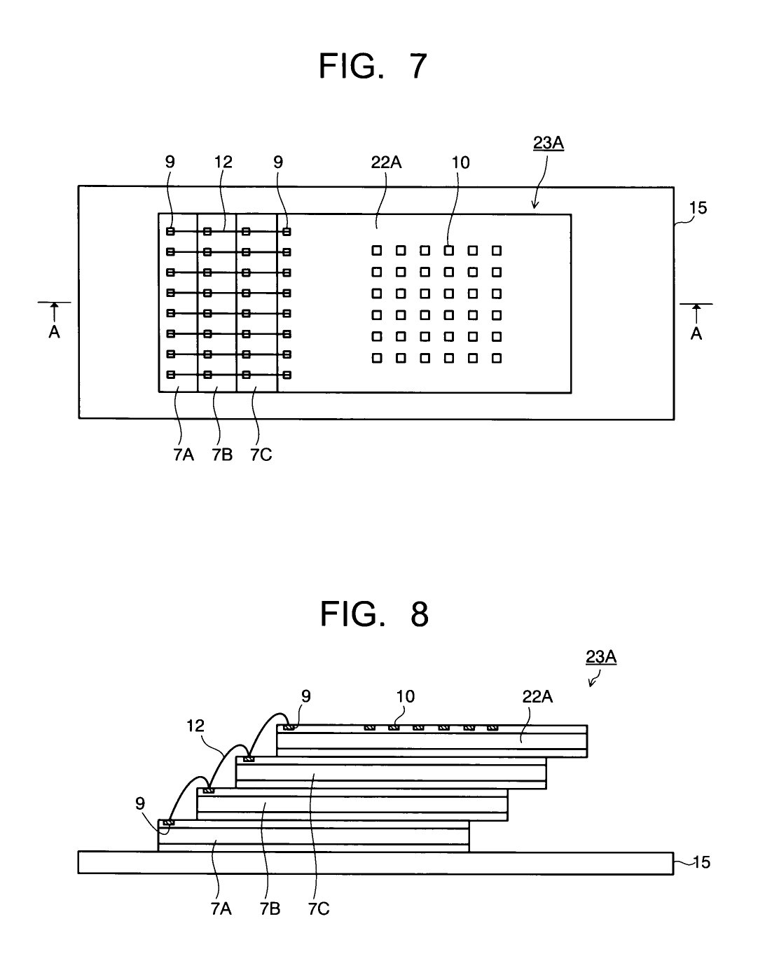

A concrete manufacturing process of first and second chip units 23A, 23B will be described with reference to FIG. 7 and FIG. 8. The first and second chip units 23A, 23B are manufactured by the same manufacturing process. FIG. 7 and FIG. 8 show the manufacturing process of the first chip unit 23A. First, a plurality of semiconductor chips 7A, 7B, 7C, 22A are stacked on a support plate 15. The semiconductor chips 7A, 7B, 7C, 22A are stacked in a step-like shape to expose electrode pads 9 thereof. The semiconductor chip 22A having test pads 10 is used for at least an uppermost level of the chip unit 23A.

Next, the electrode pads 9 of the semiconductor chips 7A, 7B, 7C, 22A stacked on the support plate 15 are electrically connected by metal wires 12. Since the test pads 10 of the semiconductor chip 22A positioned in the uppermost level is rewired from the electrode pads 9, the electrode pads 9 of the plural semiconductor chips 7A, 7B, 7C, 22A are electrically connected to the test pads 10 via first connecting members 12.

Since the semiconductor chip 22A having the test pads 10 is stacked in the uppermost level of the chip unit 23A, the test pads 10 are exposed on a top surface of the chip unit 23A. Therefore, contacting the test pads 10 with test terminals of an inspection device enables judgment of acceptance or non-acceptance of electric characteristics of the plural semiconductor chips 7A, 7B, 7C, 22A as the chip unit 23A. The inspection of the chip unit 23A can be performed on the support plate 15 or can be performed after the chip unit 23A is detached from the support plate 15.

Thereafter, the chip unit 23A having been judged to be acceptable in terms of electric characteristics in the inspection using the test pads 10 of the semiconductor chip 22A is detached from the support plate 15 and transported to a mounting process.

Otherwise, an inspection is performed after detachment from the support plate 15 in advance, and the chip unit 23A judged to be acceptable in terms of electric characteristics is transferred to the mounting process. After mounting such a chip unit 23A on a wiring board 2, through a connecting process of the chip unit 23A and the wiring board 2 by second connecting members 13, a resin sealing process and so on, the semiconductor device 21 is fabricated. Procedures are similar also in a case that a plurality of chip units 23A, 23B are stacked on the wiring board 2, and only chip units 23A, 23B having been judged non-defective are used to fabricate the semiconductor device 21.

As described above, stacking of the semiconductor chip 22 having the test pads 10 in the uppermost level of the chip unit 23 enables the inspection of the semiconductor chips 7, 22 in a stage of the chip unit 23. Since the electrode pads 9 of the semiconductor chips 7, 22 are electrically connected in the stage of the chip unit 23, the inspection of the semiconductor chips 7, 22 can be performed by using the test pads 10 of the semiconductor chip 22. Further, by fabricating the semiconductor device 21 by mounting only the chip unit 23 having been judged to be acceptable in terms of electric characteristics on the wiring board 2, yield losses of the semiconductor chips 7, 22 can be reduced and a manufacturing yield of the semiconductor device 21 can be improved.

The semiconductor device of the present invention is not limited to the above-described embodiments but the present invention can be applied to semiconductor devices of various structures in which a plurality of semiconductor chips are stacked on a wiring board. The concrete structure of the semiconductor device of the present invention can be modified in various ways as long as a basic constitution of the present invention is satisfied. Further, the embodiments can be expanded or modified within a scope of the technical spirit of the present invention and the expanded or modified embodiments are included in the technical scope of the present invention.

What is claimed is:

1. A semiconductor device, comprising:
a wiring board having internal connection terminals;
a chip unit including a plurality of semiconductor chips and an interposer stacked on the wiring board in a step-like shape so that the interposer is positioned in an uppermost level, each of the semiconductor chips having electrode pads exposed, and the interposer having test pads exposed and electrode pads wired from the test pads and exposed;
first connecting members electrically connecting between the electrode pads of the semiconductor chips and the interposer;
second connecting members electrically connecting the internal connection terminals of the wiring board and the electrode pad of the semiconductor chip or the interposer; and
a sealing resin layer formed on the wiring board to seal the chip unit together with the first and second connecting members.

2. The semiconductor device as set forth in claim 1,
wherein the semiconductor chips are judged to be acceptable in terms of electric characteristics as the chip unit in an inspection using the test pads of the interposer.

3. The semiconductor device as set forth in claim 1,
wherein the first connecting members include conductive layers and the second connecting members include metal wires.

4. The semiconductor device as set forth in claim 3,
wherein the electrode pads of the interposer are arranged along a first outer edge and a second outer edge opposed to the first outer edge, and
wherein the electrode pads arranged along the first outer edge of the interposer are electrically connected to the electrode pads of the semiconductor chip via the conductive layers, and the electrode pads arranged along the second outer edge of the interposer are electrically connected to the internal connection terminals of the wiring board via the metal wires.

5. The semiconductor device as set forth in claim 1,
wherein the first and second connecting members include metal wires.

6. The semiconductor device as set forth in claim 5,
wherein the electrode pads of the interposer, the electrode pads of the semiconductor chips and the internal connection terminals of the wiring board are sequentially connected via the metal wires.

7. The semiconductor device as set forth in claim 1,
wherein the wiring board has external connection terminals provided on a first surface opposed to a second surface on which the internal connection terminals are provided.

8. The semiconductor device as set forth in claim 1,
wherein the chip unit comprises a first chip unit including the semiconductor chips and the interposer stacked on the wiring board in the step-like shape, and a second chip unit including the semiconductor chips and the interposer stacked on the first chip unit in the step-like shape.

9. The semiconductor device as set forth in claim 8,
wherein the semiconductor chips and the interposer constituting the second chip unit are stacked in the step-like shape in a direction opposite to a stepped direction of the first chip unit.

10. The semiconductor device as set forth in claim 1,
wherein the chip unit includes semiconductor memory chips as the semiconductor chips.

11. A semiconductor device, comprising:
a wiring board having internal connection terminals;
a chip unit including a plurality of semiconductor chips stacked on the wiring board in a step-like shape, each of the plurality of semiconductor chips having electrode pads exposed;
first connecting members electrically connecting between the electrode pads of the semiconductor chips;
second connecting members electrically connecting the internal connection terminals of the wiring board and the electrode pads of the semiconductor chip; and
a sealing resin layer formed on the wiring board to seal the chip unit together with the first and second connecting members,
wherein the semiconductor chip positioned in at least an uppermost level of the chip unit has test pads rewired from the electrode pads and exposed.

12. The semiconductor device as set forth in claim 11,
wherein the semiconductor chips are judged to be acceptable in terms of electric characteristics as the chip unit in an inspection using the test pads.

13. The semiconductor device as set forth in claim 11,
wherein the test pads are provided only on a surface of the semiconductor chip positioned in the uppermost level of the chip unit.

14. The semiconductor device as set forth in claim 11,
wherein the test pads are provided on all surfaces of the semiconductor chips constituting the chip unit.

15. The semiconductor device as set forth in claim 11,
wherein the first and second connecting members include metal wires.

16. The semiconductor device as set forth in claim 15,
wherein the electrode pads of the semiconductor chips and the internal connection terminals of the wiring board are sequentially connected via the metal wires.

17. The semiconductor device as set forth in claim 11,
wherein the wiring board has external connection terminals provided on a first surface opposed to a second surface on which the internal connection terminals are provided.

18. The semiconductor device as set forth in claim 11,
wherein the chip unit comprises a first chip unit including the semiconductor chips stacked on the wiring board in the step-like shape and a second chip unit including the semiconductor chips stacked on the first chip unit in the step-like shape.

19. The semiconductor device as set forth in claim 18,
wherein the semiconductor chips constituting the second chip unit are stacked in the step-like shape in a direction opposite to a stepped direction of the first chip unit.

20. The semiconductor device as set forth in claim 11,
wherein the chip unit includes semiconductor memory chips as the semiconductor chips.
